(19) United States
(12) Patent Application Publication
(10) Pub. No.: US 2011/0298644 A1
(43) Pub. Date: Dec. 8, 2011

(54) SWITCHED-CAPACITOR AMPLIFIER AND ANALOG FRONT-END CIRCUIT

(75) Inventor: Makoto OHBA, Osaka (JP)

(73) Assignee: PANASONIC CORPORATION, Osaka (JP)

(21) Appl. No.: 13/213,979

(22) Filed: Aug. 19, 2011

Related U.S. Application Data
(63) Continuation of application No. PCT/JP2009/003272, filed on Jul. 13, 2009.

(30) Foreign Application Priority Data
Mar. 9, 2009 (JP) 2009-055047

(51) Int. Cl. H03M 1/12; H03F 3/45

(52) U.S. Cl. 341/155; 330/260

(57) ABSTRACT

In a first period, a first and a second feedback capacitors each store an electric charge dependent on a voltage level of an input signal. In a second period, a first and a second output voltages are fed back respectively through the first and the second feedback capacitors respectively to a first and a second input terminals of a differential amplifier, and a first and a second sampling capacitors respectively store a positive charge dependent on a difference between the voltage level of the input signal and the first output voltage, and a negative charge dependent on a difference between the voltage level of the input signal and the second output voltage. In a third period, the positive and the negative charges respectively stored in the first and the second sampling capacitors are respectively transferred to the first and the second input terminals of the differential amplifier.

### CROSS-REFERENCE TO RELATED APPLICATION

This is a continuation of PCT International Application PCT/JP2009/003272 filed on Jul. 13, 2009, which claims priority to Japanese Patent Application No. 2009-055047 filed on Mar. 9, 2009. The disclosures of these applications including the specifications, the drawings, and the claims are hereby incorporated by reference in its entirety.

### BACKGROUND

The technology disclosed in this specification relates to switched-capacitor amplifiers.

Conventionally, switched-capacitor amplifiers are known which each include a differential amplifier, a plurality of capacitors, and a plurality of switches, and each output a differential voltage dependent on an input signal by switching the plurality of switches. Switched-capacitor amplifiers are widely used in various applications. For example, analog image signal processors (e.g., mobile phone cameras, digital still cameras, scanners, etc.) use switched-capacitor amplifiers as correlated double samplers (CDSs), which extract pixel signals from electric signals obtained by image sensors such as charge coupled device (CCD) sensors or CMOS sensors (e.g., 1996 Symposium on VLSI Circuits: Digest of Technical Papers, pp. 96-97 (Non-Patent Document 1), Japanese Patent No. 3570301 (Patent Document 1), etc.).

FIG. 9 illustrates a configuration of a switched-capacitor amplifier disclosed in Non-Patent Document 1. In FIG. 9, first, switches 801, 807, 807, and 808 are turned on, thereby causing an input voltage VIN (feed-through voltage) to be sampled on one sampling capacitor Cs. Next, the switches 801 and 808 are turned off, and the switches 802 and 809 are turned on, thereby causing the input voltage VIN (data voltage) to be sampled on the other sampling capacitor Cs. Then, the switches 802, 807, and 807 are turned off, and the switches 804, 806, 806, and 808 are turned on, thereby causing output voltages VOUTP and VOUTN dependent on the difference between the voltages (feed-through voltage and data voltage) respectively stored in the two sampling capacitors Cs and Cs to be output. Note that this switched-capacitor amplifier further includes a switch which selectively supplies the output voltage VOUTP or a voltage Refb to a capacitor Coff, a switch which selectively supplies the output voltage VOUTN or a voltage Reft to another capacitor Coff, a switch 805 which switches a connection condition between a digital-to-analog converter (DAC) and one feedback capacitor Cf, and another switch 805 which switches a connection condition between the voltage Reft and the other feedback capacitor Cf.

FIG. 10 illustrates a configuration of a switched-capacitor amplifier disclosed in Patent Document 1. In FIG. 10, first, switches 901 and 901 are turned on, thereby causing an input voltage VIN (feed-through voltage) to be sampled on one sampling capacitor Cs, and causing a reference voltage Ref to be sampled on the other sampling capacitor Cs. Next, the switches 901 and 901 are turned off, and switches 902 and 902 are turned on, thereby causing the input voltage VIN (data voltage) to be supplied to the sampling capacitor Cs charged to the feed-through voltage, and causing the output voltages VOUTP and VOUTN dependent on the difference between the feed-through voltage and the data voltage to be output.

Here, let the feed-through voltage be denoted by “Vf,” and the data voltage be denoted by “Vd.” The input-output characteristics of the conventional CDSs shown in FIGS. 9 and 10 can be expressed as Equation A shown below.

$$VOUTP - VOUTN = - \frac{Cs}{Cf} ( Vd - Vf ) \qquad ( Equation A )$$

As shown in Equation A, the amplifier gain of a conventional CDS is equivalent to the capacitance ratio (Cs/Cf) of a sampling capacitor Cs to a feedback capacitor Cf In addition, the closed-loop bandwidth of a switched-capacitor amplifier is proportional to a tail current of the differential amplifier and a feedback factor β. Here, let the capacitance ratio (Cs/Cf) be denoted by “α.” Then, the feedback factor β is given by Equation B as follows:

$$β = \frac{Cf}{Cs + Cf} = \frac{1}{α + 1} \qquad ( Equation B )$$

As shown in Equation B, the feedback factor β is inversely proportional to the capacitance ratio (Cs/Cf).

### SUMMARY

However, in the conventional switched-capacitor amplifiers, an increase of the capacitance ratio of a sampling capacitor to a feedback capacitor in order to increase the amplifier gain causes an increase in the capacitor area. Moreover, an increase of the capacitance ratio causes the feedback factor to decrease, thereby causing the settling characteristic of the switched-capacitor amplifier to degrade. Furthermore, in order to reduce a decrease in closed-loop bandwidth due to a decrease of the feedback factor, the tail current of the differential amplifier needs to be increased. Accordingly, it is difficult to reduce the power consumption.

Thus, it is an object of the technology disclosed in this specification to provide a switched-capacitor amplifier capable of achieving an amplifier gain higher than the capacitance ratio of a sampling capacitor to a feedback capacitor.

According to an aspect of the present invention, a switched-capacitor amplifier includes a differential amplifier having a first and a second input terminals and a first and a second output terminals, a first and a second feedback capacitors, a first and a second sampling capacitors, and a connection controller. The connection controller, in a first period, stores an electric charge dependent on a voltage level of an input signal in each of the first and the second feedback capacitors; in a second period, feeds back a first and a second output voltages at the first and the second output terminals respectively through the first and the second feedback capacitors respectively to the first and the second input terminals so that the first and the second output voltages are kept at the voltage level of the input signal in the first period, and stores a positive charge dependent on a difference between the voltage level of the input signal and the first output voltage, and a negative charge dependent on a difference between the voltage level of the input signal and the second output voltage, respectively in the first and the second sampling capacitors; and in a third period, transfers the positive and the negative charges stored in the first and the second sampling capacitors respectively to the first and the second input terminals, and feeds back the first and the second output voltages respectively through the first and the second feedback capacitors respectively to the first and the second input terminals. The switched-capacitor amplifier described above achieves an amplifier gain which is higher than the capacitance ratio of a sampling capacitor to a feedback capacitor (for example, the amplifier gain can be set to twice as large as the capacitance ratio). Thus, even if the capacitance ratio is equivalent to that of a conventional one, the amplifier gain can be increased. Moreover, even if the amplifier gain is equivalent to that of a conventional one, the capacitance ratio can be reduced, thereby allowing the capacitor area to be reduced, and allowing the feedback factor to be increased.

The switched-capacitor amplifier may further include a common mode feedback circuit configured to control a tail current of the differential amplifier so that a common mode voltage of the differential amplifier becomes a predetermined target voltage. Such a configuration allows the common mode voltage to be stabilized at a predetermined voltage.

The differential amplifier may include a current control transistor configured to control the tail current, and the common mode feedback circuit may include a first and a second capacitors, one end of each of which is connected to a gate of the current control transistor, a third and a fourth capacitors respectively connected between the first and the second output terminals and the gate of the current control transistor, a first switching section configured to, in the first period, supply a control voltage to the gate of the current control transistor, and in the second and the third periods, stop supplying the control voltage, and a second switching section configured to, in the first and the second periods, supply a setting voltage to the other end of each of the first and the second capacitors, and in the third period, connect the other ends of the first and the second capacitors respectively to the first and the second output terminals. Adjusting the capacitance ratio between the first and the third capacitors (or the capacitance ratio between the second and the fourth capacitors) allows the common mode voltage to be arbitrarily set.

In addition, the connection controller may, in the first period, store an electric charge dependent on a difference between the voltage level of the input signal and a first reference voltage in the first feedback capacitor, and may store an electric charge dependent on a difference between the voltage level of the input signal and a second reference voltage in the second feedback capacitor. Such a configuration allows the amplitude of the differential voltage composed of the first and the second output voltages to be arbitrarily set.

### BRIEF DESCRIPTION OF THE DRAWINGS

FIG. 1 is a diagram illustrating an example configuration of an imaging device according to the first embodiment.

FIG. 2 is a diagram illustrating an example configuration of the switched-capacitor amplifier shown in FIG. 1.

FIG. 3 is a timing diagram to explain an operation of the switched-capacitor amplifier shown in FIG. 2.

FIG. 4 is a diagram illustrating an example configuration of the differential amplifier and the common mode feedback circuit shown in FIG. 2.

FIG. 5 is a diagram to explain a variation of the common mode feedback circuit shown in FIG. 4.

FIG. 6 is a diagram illustrating an example configuration of an imaging device according to the second embodiment.

FIG. 7 is a diagram illustrating an example configuration of the switched-capacitor amplifier shown in FIG. 6.

FIG. 8A is a waveform diagram to explain the amplitude of the differential voltage in the switched-capacitor amplifier shown in FIG. 2.

FIG. 8B is a waveform diagram to explain the amplitude of the differential voltage in the switched-capacitor amplifier shown in FIG. 7.

FIG. 9 is a diagram illustrating an example configuration of a conventional switched-capacitor amplifier.

FIG. 10 is a diagram illustrating another example configuration of a conventional switched-capacitor amplifier.

### DETAILED DESCRIPTION

Example embodiments will be described below in detail with reference to the drawings, in which like reference characters indicate the same or equivalent components, and the explanation thereof will be omitted.

### First Embodiment

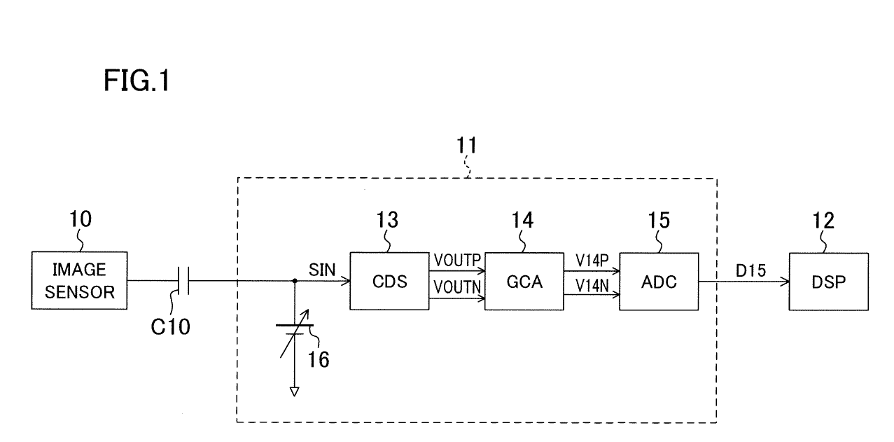

FIG. 1 illustrates an example configuration of an imaging device according to the first embodiment. The imaging device includes an image sensor 10 which photoelectrically converts a video of an object into an electrical signal, an analog front-end circuit 11 which converts the electrical signal obtained by the image sensor 10 into digital data D15, and a digital signal processor (DSP) 12 which digitally processes the digital data D15 obtained by the analog front-end circuit 11. The image sensor 10 is, for example, a CCD image sensor or a CMOS image sensor. Here, the analog front-end circuit 11 is connected through a capacitor C10 to the image sensor 10 (AC-coupled).

The analog front-end circuit 11 includes a switched-capacitor amplifier 13, a gain-controlled amplifier (GCA) 14, an analog-to-digital converter (ADC) 15, and a variable direct current (DC) source 16. The switched-capacitor amplifier 13 is used as a correlated double sampler (CDS), and performs correlated double sampling on an input signal SIN (electrical signal supplied through the capacitor C10), thereby converts the input signal SIN into a differential voltage composed of output voltages VOUTP and VOUTN. The GCA 14 amplifies the differential voltage from the switched-capacitor amplifier 13, and outputs the obtained signals as a differential voltage composed of output voltages V14P and V14N. The ADC 15 converts the differential voltage from the GCA 14 to the digital data D15. The variable DC source 16 adjusts the voltage level of the input signal SIN so that the output voltages VOUTP and VOUTN fall within the output range of the switched-capacitor amplifier 13.

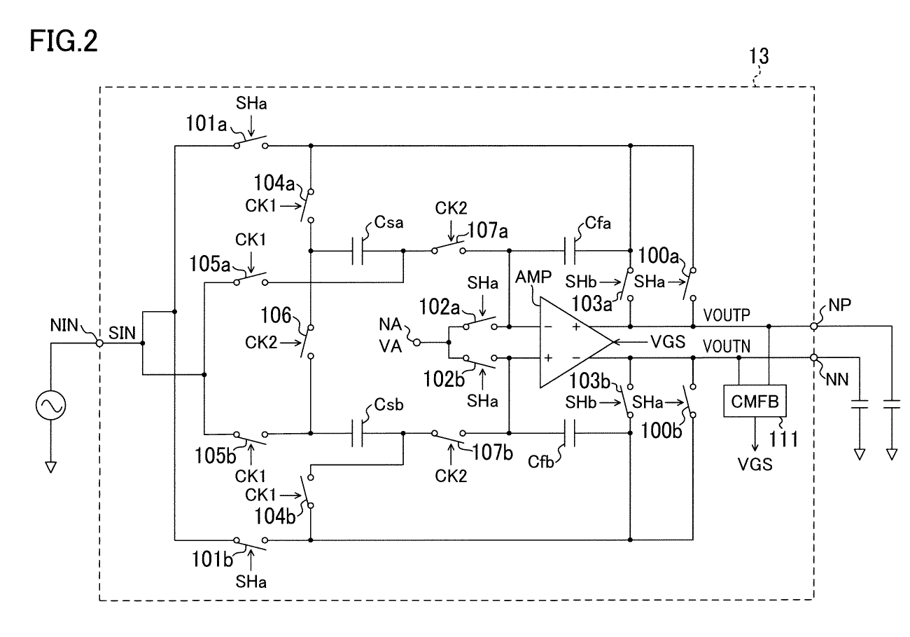

FIG. 2 illustrates an example configuration of the switched-capacitor amplifier 13 shown in FIG. 1. The switched-capacitor amplifier 13 includes a two-input two-output differential amplifier AMP, feedback capacitors Cfa and Cfb, sampling capacitors Csa and Csb, switches 100a, 100b, 101a, 101b, . . . , 107a, and 107b (connection controller), and a common mode feedback circuit (CMFB) 111. FIG. 2 also illustrates an alternate current source and a capacitor pair as a simple model for input/output impedances.

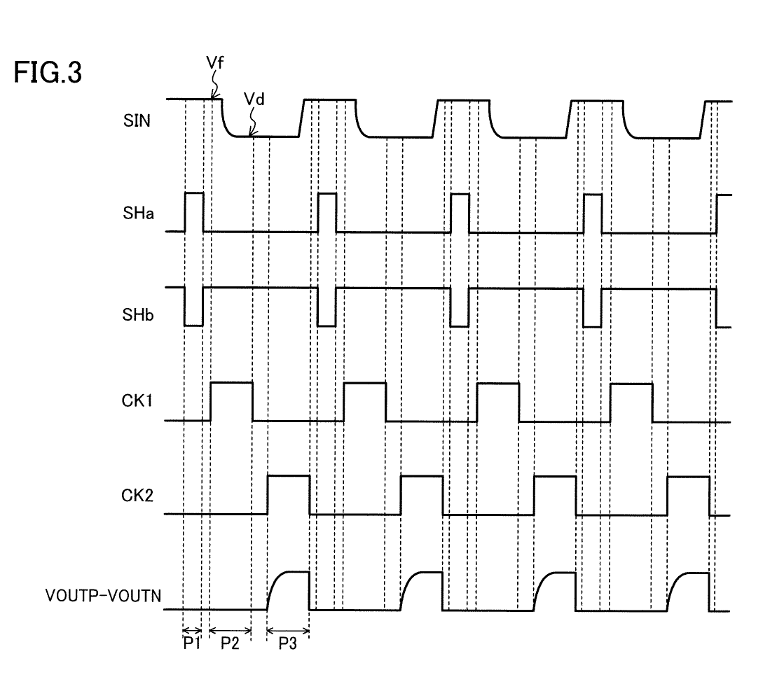

As shown in FIG. 3, the voltage level of the input signal SIN transitions from a feed-through voltage Vf to a data voltage Vd. In addition, control signals SHa, CK1, and CK2 transition from a low logic level to a high logic level respectively during periods P1, P2, and P3. A control signal SHb, which corresponds to an inverted signal of the control signal SHa, transitions from a high logic level to a low logic level during the period P1. Switching of the switches 100a, 100b, 101a, 101b, . . . , 107a, and 107b in response to the transitions of the control signals SHa, SHb, CK1, and CK2 causes the differential voltage (VOUTP−VOUTN) to be output.

Next, the operation of the switched-capacitor amplifier 13 shown in FIG. 2 will be described below.

[Period P1]

In the period P1, the control signals CK1 and CK2 are at a low logic level, and thus the switches 104a, 104b, 105a, 105b, 106, 107a, and 107b are in an Off state. When the control signal SHa transitions to a high logic level, and the control signal SHb transitions to a low logic level, the switches 100a, 100b, 101a, 101b, 102a, and 102b are turned on, and the switches 103a and 103b are turned off. Accordingly, the feedback capacitors Cfa and Cfb are connected between an input node NIN which is supplied with the input signal SIN and a node NA which is supplied with a predetermined voltage VA (e.g., a voltage equivalent to half the power supply voltage). The non-inverting and the inverting output terminals of the differential amplifier AMP are connected to the input node NIN.

Switching to such a connection condition (first connection condition) causes each of the feedback capacitors Cfa and Cfb to store an electric charge dependent on the difference between the voltage level (feed-through voltage V1) of the input signal SIN and the voltage VA. The output voltages VOUTP and VOUTN are initialized to the voltage level (Vf) of the input signal SIN.

[Period P2]

Next, in the period P2, the control signals SHa and SHb are respectively at a low logic level and at a high logic level, and thus the switches 100a, 100b, 101a, 101b, 102a, and 102b are in an Off state, and the switches 103a and 103b are in an On state. The control signal CK2 is at a low logic level, and thus the switches 106, 107a, and 107b are in an Off state. When the control signal CK1 transitions to a high logic level, the switches 104a, 104b, 105a, and 105b are turned on. Accordingly, the inverting and the non-inverting input terminals of the differential amplifier AMP are disconnected from the node NA, and thus the non-inverting and the inverting output terminals of the differential amplifier AMP are respectively connected through the feedback capacitors Cfa and Cfb to the inverting and the non-inverting input terminals of the differential amplifier AMP. One end of the sampling capacitor Csa is connected to the non-inverting output terminal of the differential amplifier AMP, while the other end of the sampling capacitor Csa is connected to the input node NIN. On the contrary, one end of the sampling capacitor Csb is connected to the input node NIN, while the other end of the sampling capacitor Csb is connected to the inverting output terminal of the differential amplifier AMP.

Switching to such a connection condition (second connection condition) causes the output voltages VOUTP and VOUTN to be fed back respectively through the feedback capacitors Cfa and Cfb respectively to the inverting and the non-inverting input terminals of the differential amplifier AMP so that the output voltages VOUTP and VOUTN are kept at the voltage level (Vf) of the input signal SIN in the period P1. The sampling capacitor Csa stores a positive charge dependent on the difference between the voltage level of the input signal SIN and the output voltage VOUTP, while the sampling capacitor Csb stores a negative charge (electric charge having an opposite polarity with respect to the electric charge stored in the sampling capacitor Csa) dependent on the difference between the voltage level of the input signal SIN and the output voltage VOUTN.

The voltage level of the input signal SIN in the period P2 corresponds to the data voltage Vd, and the output voltages VOUTP and VOUTN correspond to the feed-through voltage Vf. Here, let the capacitance value of the sampling capacitors Csa and Csb be denoted by “Cs,” and the capacitance value of the feedback capacitors Cfa and Cfb be denoted by “Cf.” The electric charges Qsa, Qsb, Qfa, and Qfb respectively stored in the sampling capacitors Csa and Csb and in the feedback capacitors Cfa and Cfb during the period P2 can be expressed as follows:

Qsa=Cs(Vf−Vd)Qfa=Cf(Vf−Va)

Qsb=−Cs(Vf−Vd)Qfb=Cf(Vf−Va)

[Period P3]

Next, in the period P3, the control signals SHa and SHb are respectively at a low logic level and at a high logic level, and thus the switches 100a, 100b, 101a, 101b, 102a, and 102b are in an Off state, and the switches 103a and 103b are in an On state. In addition, the control signal CK1 is at a low logic level, and thus the switches 104a, 104b, 105a, and 105b are in an Off state. When the control signal CK2 transitions to a high logic level, the switches 106, 107a, and 107b are turned on. Accordingly, one ends of the sampling capacitors Csa and Csb are connected to each other, and the other ends of the sampling capacitors Csa and Csb are connected respectively to the inverting and the non-inverting input terminals of the differential amplifier AMP. In addition, the non-inverting and the inverting output terminals of the differential amplifier AMP are respectively connected through the feedback capacitors Cfa and Cfb to the inverting and the non-inverting input terminals of the differential amplifier AMP.

Switching to such a connection condition (third connection condition) causes the positive and the negative charges stored in the sampling capacitors Csa and Csb to be transferred to the feedback capacitors Cfa and Cfb.

The voltages at one ends of the sampling capacitors Csa and Csb, and the voltages at the other ends of the sampling capacitors Csa and Csb (at the inverting and the non-inverting input terminals of the differential amplifier AMP) each correspond to the average voltage of the voltage level (Vf) of the input signal SIN in the period P1 and the voltage level (Vd) of the input signal SIN in the period P2, that is, (Vf+Vd)/2. Here, the electric charges Qsa′, Qsb′, Qfa′, and Qfb′ respectively stored in the sampling capacitors Csa and Csb and the feedback capacitors Cfa and Cfb during the period P3 can be expressed as follows:

$$\begin{matrix}{Qsa}^{′} = 0 & {Qfa}^{′} = Cf ( VOUTP - \frac{Vf + Vd}{2} ) \\ {Qsb}^{′} = 0 & {Qfb}^{′} = Cf ( VOUTN - \frac{Vf + Vd}{2} )\end{matrix}$$

Since the law of conservation of charge holds for the sampling capacitors Csa and Csb and the feedback capacitors Cfa and Cfb, Equations 1 and 2 below are obtained.

$$\begin{matrix}Cs ( Vf - Vd ) + Cf ( Vf - Va ) = Cf ( VOUTP - \frac{Vf + Vd}{2} ) & ( Equation 1 ) \\ - Cs ( Vf - Vd ) + Cf ( Vf - Va ) = Cf ( VOUTN - \frac{Vf + Vd}{2} ) & ( Equation 2 )\end{matrix}$$

From Equations 1 and 2, the input-output characteristic of the switched-capacitor amplifier 13 shown in FIG. 2 can be expressed as Equation 3 below.

$$VOUTP - VOUTN = - 2 \frac{Cs}{Cf} ( Vd - Vf ) \qquad ( Equation 3 )$$

As shown in Equation 3, the amplifier gain of the switched-capacitor amplifier 13 is twice as high as the capacitance ratio of the sampling capacitor Csa (Csb) to the feedback capacitor Cfa (Cfb). In addition, the amplitude of the differential voltage (VOUTP−VOUTN) in the period P3 depends on the difference between the voltage level (Vf) of the input signal SIN in the period P1 and the voltage level (Vd) of the input signal SIN in the period P2 (see FIG. 3).

Thus, the amplifier gain of the switched-capacitor amplifier 13 can be higher than the capacitance ratio (Cs/Cf). Accordingly, even if the capacitance ratio (Cs/Cf) is similar to that of a conventional one, a higher amplifier gain can be obtained. In addition, even if the amplifier gain is similar to that of a conventional one, a smaller capacitance ratio (Cs/Cf) can be obtained, thereby allowing the capacitor area to be reduced. For example, if the amplifier gain is set to “2” for a conventional switched-capacitor amplifier, the capacitance value of a feedback capacitor Cf is set to “C,” and the capacitance value of a sampling capacitor Cs is set to “2C,” and thus the total capacitance value is “6C” (=C+C+2C+2C). Meanwhile, in the switched-capacitor amplifier 13 shown in FIG. 2, the capacitance values of the sampling capacitor Csa (Csb) and of the feedback capacitor Cfa (Cfb) can be set to “C,” and thus the total capacitance value can be set to “4C” (=C+C+C+C). Accordingly, the capacitor area can be reduced to two thirds of that of the conventional one.

Moreover, since the capacitance ratio (Cs/Cf) can be reduced, the feedback factor β can be increased. This eliminates the need to increase the tail current of the differential amplifier AMP in order to increase the closed-loop bandwidth BW, thereby allowing the power consumption to be reduced. For example, if the amplifier gain is set to “2,” Equation B shows that the conventional switched-capacitor amplifier has the feedback factor β of ⅓(=C/(2C+C)). Meanwhile, in the switched-capacitor amplifier 13 shown in FIG. 2, the feedback factor β can be set to ½(=C/(C+C)), and thus the closed-loop bandwidth BW can be set to 3/2 times higher than that of the conventional one. In addition, if the closed-loop bandwidth BW is allowed to be a similar value to that of the conventional one, the tail current of the differential amplifier AMP can be reduced to two thirds of that of the conventional one.

Furthermore, since the feedback factor β can be increased, the settling characteristic of the switched-capacitor amplifier can be improved. That is, the time required for the voltage levels of the output voltages VOUTP and VOUTN to converge can be reduced. For example, comparing to the switched-capacitor amplifier shown in FIG. 10, the amplification period is reduced (if the amplifier gain is set to “2,” the amplification period is reduced to two thirds); however, the amount of reduction of the amplification period can be compensated by the amount of increase (3/2 times) of the feedback factor β.

(Common Mode Feedback Circuit)

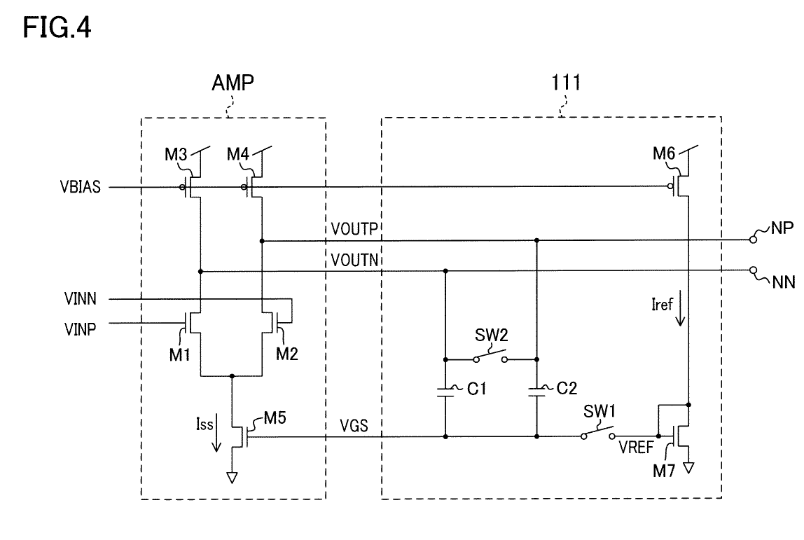

FIG. 4 illustrates an example configuration of the differential amplifier AMP and the common mode feedback circuit 111 shown in FIG. 2. The differential amplifier AMP includes transistors M1 and M2 whose gates respectively receive an input voltage VINP supplied to the non-inverting input terminal and an input voltage VINN supplied to the inverting input terminal, transistors M3 and M4 whose gates receive a bias voltage VBIAS, and a transistor M5 (current control transistor) which controls the amount of current of the tail current Iss based on a control voltage VGS from the common mode feedback circuit 111.

The common mode feedback circuit 111 includes transistors M6 and M7, capacitors C1 and C2, and switches SW1 and SW2. The transistor M7 receives a reference current Iref dependent on the bias voltage VBIAS supplied to the gate of the transistor M6, and a control voltage VREF dependent on the reference current Iref is generated at the gate of the transistor M7. One end of each of the capacitors C1 and C2 is connected to the gate of the transistor M5, and the other ends of the capacitors C1 and C2 are respectively supplied with the output voltages VOUTN and VOUTP.

In the period P1, the switches SW1 and SW2 are turned on. Thus, the control voltage VREF is supplied to the gate of the transistor M5 as the control voltage VGS. In addition, the switches 100a and 100b (FIG. 2) are in an On state, and thus the output voltages VOUTP and VOUTN are at the signal level (feed-through voltage Vf) of the input signal SIN. Accordingly, the capacitors C1 and C2 store electric charges dependent on the difference between the feed-through voltage Vf and the control voltage VREF. Next, in the period P2, the switches SW1 and SW2 are turned off. Thus, the control voltage VREF is no longer supplied to the transistor M5. In addition, the output voltages VOUTP and VOUTN are at the signal level (Vf) of the input signal SIN in the period P1, and thus the capacitors C1 and C2 each store an electric charge dependent on the difference between the feed-through voltage Vf and the control voltage VGS. Next, in the period P3, the switches SW1 and SW2 remain in an Off state. Accordingly, the control voltage VGS changes so that the common mode voltage of the differential amplifier AMP becomes a predetermined voltage. The control voltage VGS can be expressed as Equation 4 below.

$$VGS = VREF + ( \frac{VOUTP - VOUTN}{2} - Vf ) \qquad ( Equation 4 )$$

The reference current Iref is equivalent to the sum of the currents which respectively flow through the transistors M3 and M4. If the control voltage VGS is the same as the control voltage VREF, the tail current Iss of the differential amplifier AMP is the same as the reference current Iref, and thus the output voltages VOUTP and VOUTN remain constant. Here, if the common mode voltage (VOUTP+VOUTN)/2 of the differential amplifier AMP exceeds the feed-through voltage Vf, the control voltage VGS exceeds the control voltage VREF. As a result, the tail current Iss increases, while the output voltages VOUTP and VOUTN decrease. Thus, the common mode feedback circuit 111 controls the tail current Iss of the differential amplifier AMP so that the common mode voltage of the differential amplifier AMP becomes a predetermined target voltage (here, the feed-through voltage Vf). In general, the common mode voltage of the differential amplifier AMP is set to a voltage level equivalent to half the power supply voltage. If the feed-through voltage Vf is not equivalent to half the power supply voltage, the common mode voltage can be set to a voltage level equivalent to half the power supply voltage by setting the voltage of the variable DC source 16 shown in FIG. 1 to a voltage level equivalent to half the power supply voltage.

(Variation of Common Mode Feedback Circuit)

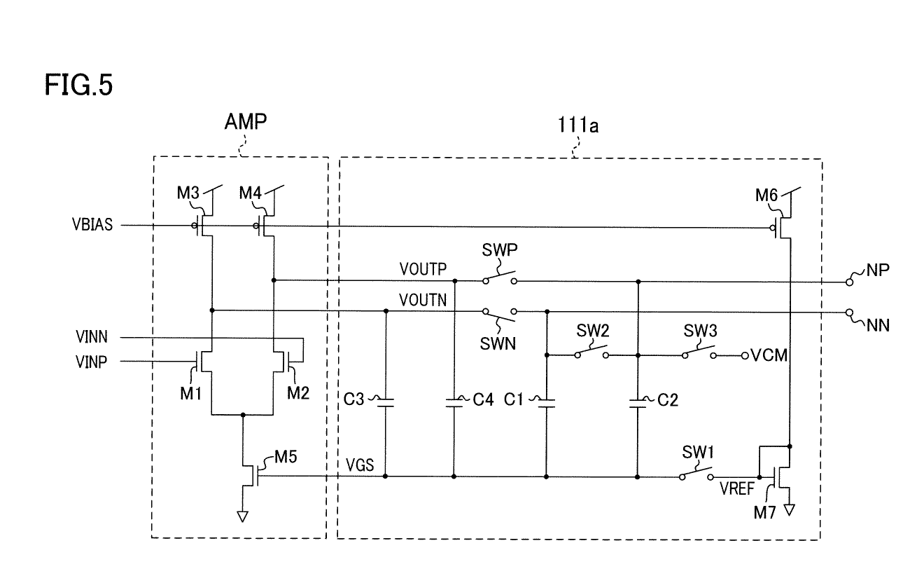

The switched-capacitor amplifier 13 may include a common mode feedback circuit 111a shown in FIG. 5 instead of the common mode feedback circuit 111 shown in FIGS. 2 and 4. The common mode feedback circuit 111a further includes, in addition to the components shown in FIG. 4, switches SW3, SWP, and SWN, and capacitors C3 and C4 respectively connected between the inverting and the non-inverting output terminals of the differential amplifier AMP and the gate of the transistor M5. The switch SWP switches a connection condition between the non-inverting output terminal of the differential amplifier AMP and an output node NP, and the switch SWN switches a connection condition between the inverting output terminal of the differential amplifier AMP and an output node NNk. The other ends of the capacitors C1 and C2 are respectively connected to the output nodes NN and NP.

In the period P1, the switches SW1, SW2, and SW3 are turned on, and the switches SWP and SWN are turned off. Accordingly, the other ends of the capacitors C1 and C2 are disconnected from the inverting and the non-inverting output terminals of the differential amplifier AMP, and are connected to a node which is supplied with a setting voltage VCM (e.g., a voltage equivalent to half the power supply voltage), and thus the capacitors C1 and C2 each store an electric charge dependent on the difference between the setting voltage VCM and the control voltage VREF. Meanwhile, the capacitor C3 stores an electric charge dependent on the difference between the output voltage VOUTN (feed-through voltage Vf) and the control voltage VREF, and the capacitor C4 stores an electric charge dependent on the difference between the output voltage VOUTP (feed-through voltage Vf) and the control voltage VREF. Next, in the period P2, the switch SW1 is turned off. The switches SW2 and SW3 remain in an On state, and the switches SWP and SWN remain in an Off state. Next, in the period P3, the switches SW2 and SW3 are turned off, and the switches SWN and SWP are turned on. The switch SW1 remains in an Off state. Here, let the capacitance value of the capacitors C3 and C4 be denoted by “C,” and the capacitance value of the capacitors C1 and C2 be denoted by “nC,” where n is a natural number. The control voltage VGS can be expressed as Equation 5 below.

$$VGS = VREF + ( \frac{VOUTP - VOUTN}{2} - ( \frac{Vf + nVCM}{1 + n} ) ) \qquad ( Equation 5 )$$

In Equation 5, the term Vf in Equation 4 is replaced with (Vf+nVCM)/(1+n). That is, the common mode feedback circuit 111a controls the tail current Iss of the differential amplifier AMP so that the common mode voltage of the differential amplifier AMP becomes a predetermined target voltage (Vf+nVCM)/(1+n). In addition, adjusting the capacitance ratio between the capacitors C1 (C2) and C3 (C4) allows the common mode voltage of the differential amplifier AMP to be arbitrarily set.

### Second Embodiment

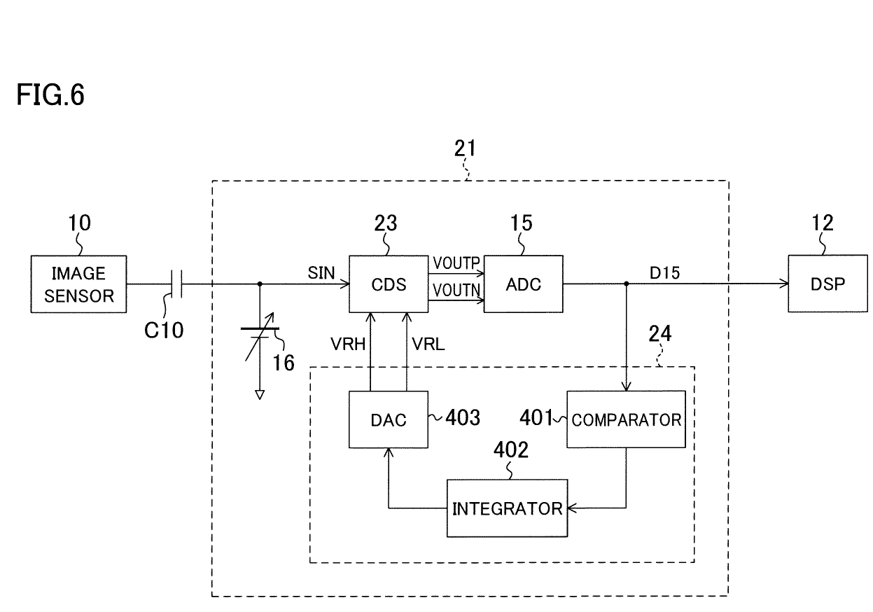

FIG. 6 illustrates an example configuration of an imaging device according to the second embodiment. The imaging device includes an analog front-end circuit 21 instead of the analog front-end circuit 11 shown in FIG. 1. The analog front-end circuit 21 includes a switched-capacitor amplifier 23 and a correction circuit 24 instead of the switched-capacitor amplifier 13 and the GCA 14. The switched-capacitor amplifier 23 is used as a correlated double sampler (CDS). The ADC 15 converts the differential voltage composed of the output voltages VOUTP and VOUTN into the digital data D15. The other part of the configuration is similar to that of FIG. 1.

The correction circuit 24 corrects reference voltages VRH and VRL based on the digital data D15 so that the digital data D15 becomes a predetermined target value. For example, the correction circuit 24 is an optical black correction circuit, and corrects the reference voltages VRH and VRL so that the digital data D15 will be a predetermined reference value if a black level signal (electrical signal corresponding to an optical black pixel region of the image sensor 10) is provided to the switched-capacitor amplifier 23 from the image sensor 10. The correction circuit 24 includes a comparator 401 which compares the digital data D15 with a target value, an integrator 402 which integrates the comparison result by the comparator 401, and a digital-to-analog converter (DAC) 403 which converts the output of the integrator 402 into the reference voltages VRH and VRL. For example, the comparator 401 outputs “+1” if the value of the digital data D15 is greater than the target value, and outputs “−1” if the value of the digital data D15 is less than the target value. The integrator 402 accumulates the outputs (“+1” or “−1”) of the comparator 401. A lower output of the integrator 402 causes the DAC 403 to output a higher reference voltage VRH and a lower reference voltage VRL.

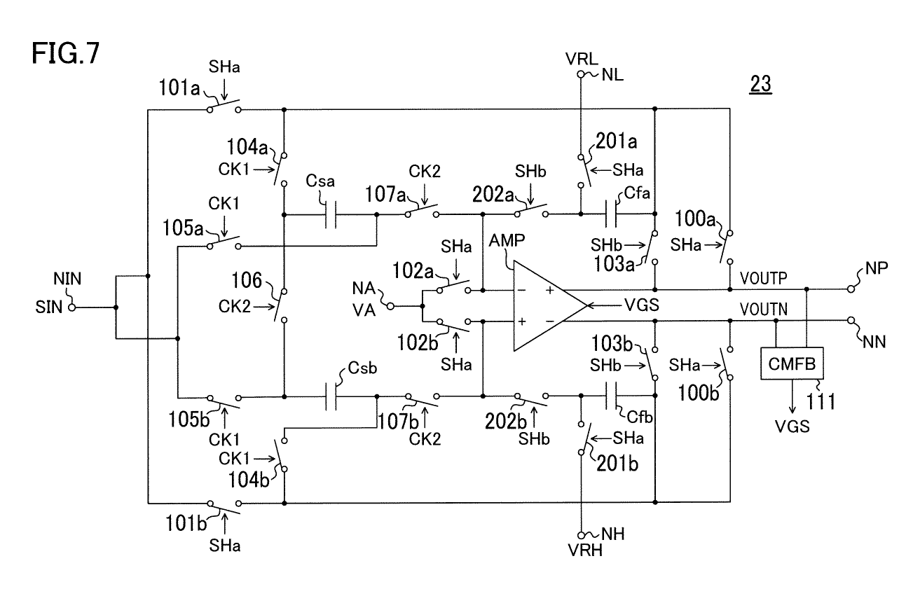

FIG. 7 illustrates an example configuration of the switched-capacitor amplifier 23 shown in FIG. 6. The switched-capacitor amplifier 23 includes switches 201a, 201b, 202a, and 202b in addition to the components shown in FIG. 2. The other part of the configuration is similar to that of FIG. 2. The switching operations of the switches 100a, 100b, . . . , 107a, and 107b are also similar to those of FIG. 2.

In the period P1, when the control signal SHa transitions to a high logic level, and the control signal SHb transitions to a low logic level, the switches 201a and 201b are turned on, and the switches 202a and 202b are turned off. Thus, one end and the other end of the feedback capacitor Cfa are respectively connected to the input node NIN and to a reference node NL (a node supplied with the reference voltage VRL), and one end and the other end of the feedback capacitor Cfb are respectively connected to the input node NIN and to a reference node NH (a node supplied with the reference voltage VRH). Switching to such a connection condition (fourth connection condition) causes the feedback capacitor Cfa to store an electric charge dependent on the difference between the voltage level (Vf) of the input signal SIN and the reference voltage VRL, and causes the feedback capacitor Cfb to store an electric charge dependent on the difference between the voltage level (VD of the input signal SIN and the reference voltage VRH.

Meanwhile, in the periods P2 and P3, the control signals SHa and SHb are respectively at a low logic level and a high logic level, and thus the switches 201a and 201b are in an Off state, and the switches 202a and 202b are in an On state. Thus, the connection condition formed by the differential amplifier AMP, the feedback capacitors Cfa and Cfb, and the sampling capacitors Csa and Csb is switched to the second connection condition in the period P2, and is switched to the third connection condition in the period P3.

The input-output characteristic of the switched-capacitor amplifier 23 can be expressed as Equation 6 below.

$$VOUTP - VOUTN = - 2 \frac{Cs}{Cf} ( Vd - Vf ) + ( VRH - VRL ) \qquad ( Equation 6 )$$

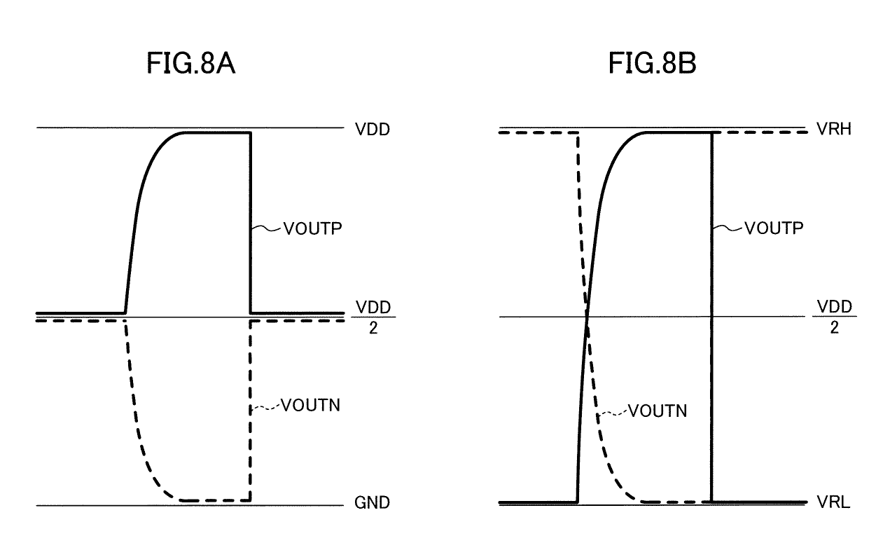

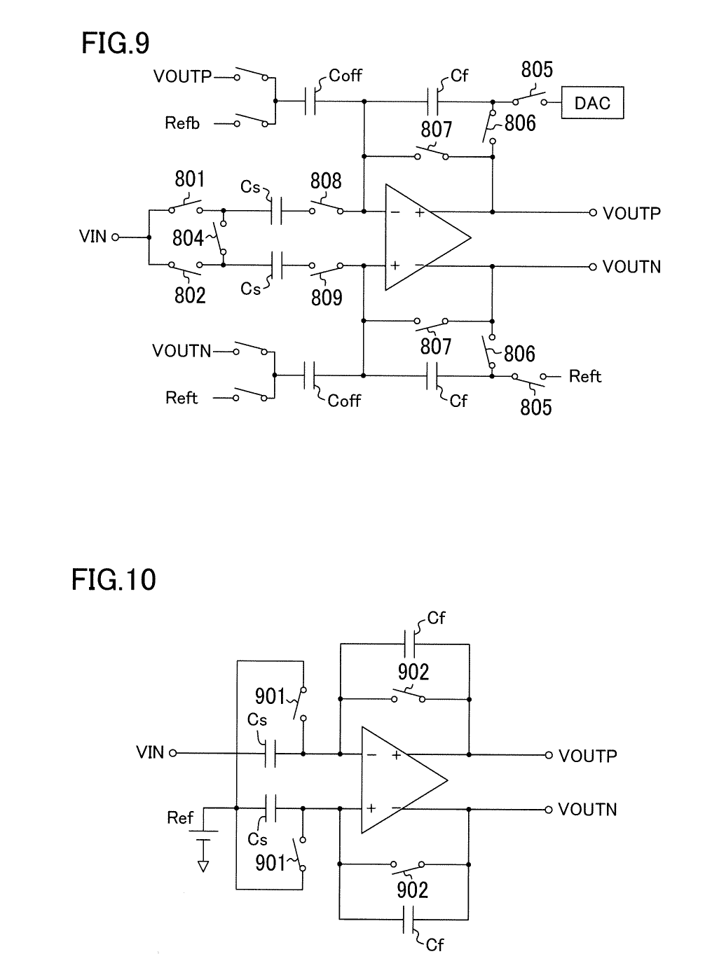

As shown in Equation 6, adjusting the reference voltages VRH and VRL allows the amplitude of the differential voltage (VOUTP−VOUTN) to be arbitrarily set. For example, in the switched-capacitor amplifier 13 shown in FIG. 2, the output voltage VOUTP varies in a range from the power supply voltage VDD to the central voltage (VDD/2), and the output voltage VOUTN varies in a range from the central voltage (VDD/2) to the ground voltage GND, as shown in FIG. 8A. Meanwhile, in the switched-capacitor amplifier 23 shown in FIG. 7, the output voltages VOUTP and VOUTN vary in a range from the reference voltage VRH to the reference voltage VRL as shown in FIG. 8B. Thus, the amplitude of the differential voltage (VOUTP−VOUTN) can be adapted to the input range of the ADC 15, thereby eliminating the need to provide the GCA 14. Accordingly, the circuit area and the power consumption of the analog front-end circuit can be reduced.

The switched-capacitor amplifier 23 may include the common mode feedback circuit 111a shown in FIG. 5 instead of the common mode feedback circuit 111 shown in FIG. 7.

In the embodiments described above, the arrangements of the switches of the switched-capacitor amplifiers 13 and 23 are not limited to those shown in FIGS. 2 and 7. That is, a plurality of switches only need to be arranged so that the connection condition formed by the differential amplifier AMP, the feedback capacitors Cfa and Cfb, and the sampling capacitors Csa and Csb is switched between the first connection condition (or the fourth connection condition), the second connection condition, and the third connection condition. Similarly, the arrangements of the switches of the common mode feedback circuits 111 and 111a are not limited to those shown in FIGS. 4 and 5.

As described above, the switched-capacitor amplifiers described above can each have an amplifier gain higher than the capacitance ratio, and thus, are useful for analog image signal processors such as mobile phone cameras, digital still cameras, scanners, etc.

It is to be understood that the foregoing embodiments are illustrative in nature, and are not intended to limit the scope of the invention, application of the invention, or use of the invention.

What is claimed is:

1. A switched-capacitor amplifier, comprising:
a differential amplifier having a first and a second input terminals and a first and a second output terminals;
a first and a second feedback capacitors;
a first and a second sampling capacitors; and
a connection controller,
wherein
the connection controller
in a first period, stores an electric charge dependent on a voltage level of an input signal in each of the first and the second feedback capacitors,
in a second period, feeds back a first and a second output voltages at the first and the second output terminals respectively through the first and the second feedback capacitors respectively to the first and the second input terminals so that the first and the second output voltages are kept at the voltage level of the input signal in the first period, and stores a positive charge dependent on a difference between the voltage level of the input signal and the first output voltage, and a negative charge dependent on a difference between the voltage level of the input signal and the second output voltage, respectively in the first and the second sampling capacitors, and
in a third period, transfers the positive and the negative charges stored in the first and the second sampling capacitors respectively to the first and the second input terminals, and feeds back the first and the second output voltages respectively through the first and the second feedback capacitors respectively to the first and the second input terminals.

2. The switched-capacitor amplifier of claim 1, wherein
the connection controller can switch between a first, a second, and a third connection conditions respectively corresponding to the first, the second, and the third periods; and
in the first connection condition, the first and the second feedback capacitors are connected in parallel with each other between an input node which is supplied with the input signal and a predetermined node which is supplied with a predetermined voltage,
in the second connection condition, the first and the second output terminals are connected respectively through the first and the second feedback capacitors respectively to the first and the second input terminals, one end and the other end of the first sampling capacitor are respectively connected to the first output terminal and to the input node, and one end and the other end of the second sampling capacitor are respectively connected to the input node and to the second output terminal, and
in the third connection condition, the first and the second output terminals are connected respectively through the first and the second feedback capacitors respectively to the first and the second input terminals, one ends of the first and the second sampling capacitors are connected to each other, and the other ends of the first and the second sampling capacitors are connected respectively to the first and the second input terminals.

3. The switched-capacitor amplifier of claim 1, further comprising:
a common mode feedback circuit configured to control a tail current of the differential amplifier so that a common mode voltage of the differential amplifier becomes a predetermined target voltage.

4. The switched-capacitor amplifier of claim 3, wherein
the differential amplifier includes a current control transistor configured to control the tail current, and
the common mode feedback circuit includes
a first and a second capacitors, one end of each of which is connected to a gate of the current control transistor,
a third and a fourth capacitors respectively connected between the first and the second output terminals and the gate of the current control transistor,
a first switching section configured to, in the first period, supply a control voltage to the gate of the current control transistor, and in the second and the third periods, stop supplying the control voltage, and
a second switching section configured to, in the first and the second periods, supply a setting voltage to the other end of each of the first and the second capacitors, and in the third period, connect the other ends of the first and the second capacitors respectively to the first and the second output terminals.

5. The switched-capacitor amplifier of claim 1, wherein
the connection controller, in the first period, stores an electric charge dependent on a difference between the voltage level of the input signal and a first reference voltage in the first feedback capacitor, and stores an electric charge dependent on a difference between the voltage level of the input signal and a second reference voltage in the second feedback capacitor.

6. An analog front-end circuit, comprising:
an image sensor configured to convert a video of an object into an electrical signal;
a correlated double sampler configured to convert the electrical signal into a differential voltage;
a gain-controlled amplifier configured to amplify the differential voltage; and
an analog-to-digital converter configured to convert the differential voltage amplified by the gain-controlled amplifier into digital data,
wherein
the correlated double sampler is the switched-capacitor amplifier of claim 1, and
the differential voltage is composed of the first and the second output voltages.

7. An analog front-end circuit, comprising:
an image sensor configured to convert a video of an object into an electrical signal;
a correlated double sampler configured to convert the electrical signal into a differential voltage;
an analog-to-digital converter configured to convert the differential voltage into digital data; and
a correction circuit,
wherein
the correlated double sampler is the switched-capacitor amplifier of claim 5,
the differential voltage is composed of the first and the second output voltages, and
the correction circuit corrects the first and the second reference voltages based on the digital data.
